(19) United States
(12) Patent Application Publication
(10) Pub. No.: US 2026/0190679 A1
(43) Pub. Date: Jul. 2, 2026

(54) DISPLAY DEVICE AND DISPLAY PANEL

(71) Applicant: LG Display Co., Ltd., Seoul (KR)

(72) Inventors: EunHye LEE, Paju-si (KR); Hyeonchul IM, Paju-si (KR); GiSang HONG, Paju-si (KR)

(73) Assignee: LG Display Co., Ltd., Seoul (KR)

(21) Appl. No.: 19/319,309

(22) Filed: Sep. 4, 2025

(30) Foreign Application Priority Data
Dec. 27, 2024 (KR) 10-2024-0198969

(51) Int. Cl. H10K 59/126; H10K 59/131; H10K 59/65; H10K 59/80

(52) U.S. Cl. CPC H10K 59/126; H10K 59/131; H10K 59/65; H10K 59/873

(57) ABSTRACT

The present disclosure relates to a display device and display panel. An example display device includes a display panel having a normal area with a plurality of subpixels, an optical area in which an optical electronic device is located, and a link area in which a driving signal line extends from a pad area. A driving circuit is configured to transmit a driving signal through the driving signal line. The optical area includes a first moisture-proof pattern positioned between the optical electronic device and the normal area. The link area includes a second moisture-proof pattern positioned between the pad area and the normal area. By providing distinct moisture proof patterns in both the optical area and the link area, the display panel can block moisture penetration paths associated with the emission layer and with signal routing, thereby improving operational reliability and durability of the display device.

### CROSS REFERENCE TO RELATED APPLICATION

This application claims priority and benefit from Korean Patent Application No. 10-2024-0198969, filed on Dec. 27, 2024, which is hereby incorporated by reference in its entirety for all purposes as if fully set forth herein.

### TECHNICAL FIELD

Embodiments of the present disclosure relate to a display device and a display panel, and more specifically, to a display device and a display panel with a structure capable of preventing moisture from penetrating along an area where a driving signal line is formed.

### DESCRIPTION OF THE RELATED ART

As examples of display devices for displaying images using digital data, there are a liquid crystal displays (LCD) using liquid crystals and an organic light emitting displays (OLED) using organic light emitting diodes.

Among display devices, the organic light emitting display device utilizes self-luminous light emitting diodes, which provide fast response speeds and have advantages in contrast ratio, luminous efficiency, brightness, and viewing angle. In this case, the light emitting diodes can be implemented as inorganic or organic materials.

The organic light emitting display device may include organic light emitting diodes arranged in each of a plurality of subpixels disposed on a display panel, and may control the brightness of each subpixel by controlling a voltage flowing to the organic light emitting diodes to emit light, thereby displaying images.

As technology advances, these display devices can provide image-capturing functions and various sensing functions in addition to the function of displaying images. To this end, the display device has to be equipped with optical electronic devices (also referred to as light receiving devices or sensors) such as cameras and sensing sensors. In the case that an optical electronic device is disposed in an active area, the configuration with a through-hole for placing the optical electronic device may be referred to as a hole-in active area (HiAA).

The description provided in the discussion of the related art section should not be assumed to be prior art merely because it is mentioned in or associated with that section. The discussion of the related art section may include information that describes one or more aspects of the subject technology, and the description in this section does not limit the present disclosure.

### BRIEF SUMMARY

In the course of developing the present disclosure, it was found that various display devices, including organic light-emitting display devices, may experience performance degradation such as reduced reliability due to moisture entering a display panel. The present disclosure therefore provides configurations that block moisture penetration or moisture transmission through different structural arrangements.

In particular, if moisture penetrates an optical area where the optical electronic device is disposed or a link area for transmitting a driving signal to the display panel, there is a problem that a defect occurs in the driving signal line and the normal operation of the display device becomes difficult.

Accordingly, the present disclosure describes a dual zone moisture blocking strategy. In the optical area, a first moisture proof pattern (MPP1) interrupts continuity of the emission layer by introducing a recessed region that is flanked by insulating sidewalls, an undercut organic moisture insulating layer, and a supporting conductive structure. A shielding layer (SM1) is formed over the recess and functions as an upper barrier. In combination with inner and outer dams arranged around the optical through hole to confine encapsulant flow, this structure prevents lateral migration of moisture from the optical opening into the active pixel region.

In the link area, a second moisture proof pattern (MPP2) is placed between the pad and normal areas to block moisture traveling along routing paths. Here the second shielding layers (SM2) are implemented as separated islands that may be combined with dams. These can be formed either on raised regions of the interlayer dielectric or in recessed grooves in order to control topography and facilitate planarization. By shaping the shields through selective removal of upper titanium layers, leaving a wider titanium base that extends beyond the aluminum, the resulting trapezoidal profile enhances moisture resistance while maintaining smooth layering for subsequent structures.

The process includes an additional treatment to address degradation of titanium aluminum titanium stacks that occurs during development. Corrosion of the aluminum leaves voids and protrusions of titanium that otherwise provide a path for moisture ingress. A post development wet etch, such as buffered oxide etch, is applied to remove these protrusions and yield stable trapezoidal shielding structures. This same etch also deepens the recess in the optical area, which enhances the disconnection of the emission layer. The arrangements disclosed for the optical area, the link area, and the post development treatment each provide moisture barriers that correspond to the identified ingress mechanisms.

Embodiments of the present disclosure may provide a display device and a display panel including a moisture-proof pattern capable of preventing moisture from entering an optical area where an optical electronic device is disposed and a link area that supplies a driving signal to a display panel.

Embodiments of the present disclosure may provide a display device and a display panel having different structures of moisture-proof patterns formed in the optical area and the link area.

Embodiments of the present disclosure may provide a display device and a display panel having a first moisture-proof pattern in an optical area and a second moisture-proof pattern in a power line area for the process optimization of the optical area and a link area.

The tasks of the embodiments of the present disclosure are not limited to the tasks described in the present disclosure, and other tasks not described will be clearly understood by those skilled in the art from the description below.

A display device according to exemplary embodiments of the present disclosure may include a display panel including a normal area where a plurality of subpixels are disposed, an optical area where an optical electronic device is located, and a link area where a driving signal line extends from a pad area, and a driving circuit configured to transmit a driving signal through the driving signal line, wherein the optical area includes a first moisture-proof pattern formed between the optical electronic device and the normal area, and the link area includes a second moisture-proof pattern formed between the pad area and the normal area.

A display panel according to exemplary embodiments of the present disclosure may include a normal area where a plurality of subpixels are disposed, an optical area where an optical electronic device is located, and a link area where a driving signal line extends from a pad area to which a driving circuit is connected, wherein the optical area includes a first moisture-proof pattern formed between the optical electronic device and the normal area, and the link area includes a second moisture-proof pattern formed between the pad area and the normal area.

According to exemplary embodiments of the present disclosure, it is possible to provide a display device and a display panel including a moisture-proof pattern capable of preventing moisture from entering an optical area where an optical electronic device is disposed and a link area that supplies a driving signal to a display panel.

According to exemplary embodiments of the present disclosure, it is possible to provide a display device and a display panel having different structures of moisture-proof patterns formed in the optical area and the link area.

According to exemplary embodiments of the present disclosure, it is possible to provide a display device and a display panel having a first moisture-proof pattern in an optical area and a second moisture-proof pattern in a power line area for the process optimization of the optical area and a link area.

The effects of the embodiments of the present disclosure are not limited to the tasks described in the present disclosure, and other effects not described will be clearly understood by those skilled in the art from the description below.

### BRIEF DESCRIPTION OF THE SEVERAL VIEWS OF THE DRAWINGS

The present disclosure will be more fully understood from the detailed description and accompanying drawings provided below, which are provided for illustration purposes only and are not intended to limit the present disclosure.

FIG. 1 illustrates a display device according to exemplary embodiments of the present disclosure.

FIG. 2 is an exemplary plan view of a display device according to exemplary embodiments of the present disclosure.

FIG. 3 illustrates an exemplary equivalent circuit of a subpixel in a display panel according to exemplary embodiments of the present disclosure.

FIG. 4 illustrates a cross-section of a normal area of a display area in a display panel according to exemplary embodiments of the present disclosure.

FIG. 5 illustrates an example of a planar structure of an optical area in a display device according to exemplary embodiments of the present disclosure.

FIG. 6 illustrates an example of an overall cross-sectional view of a display device according to exemplary embodiments of the present disclosure.

FIG. 7 illustrates a phenomenon in which a part of a moisture-proof pattern is corroded in a display device according to exemplary embodiments of the present disclosure.

FIG. 8 is a microscopic photograph illustrating a case in which a part of a moisture-proof pattern is corroded.

FIG. 9 illustrates an example of a process of removing a tip structure of a shielding layer forming a moisture-proof pattern in a display device according to exemplary embodiments of the present disclosure.

FIGS. 10 to 14 illustrate an example of a process of forming a first moisture-proof pattern in an optical area and a second moisture-proof pattern in a link area in a display device according to exemplary embodiments of the present disclosure.

FIG. 15 illustrates a first shape of a first moisture-proof pattern and a second moisture-proof pattern in a display device according to exemplary embodiments of the present disclosure.

FIG. 16 illustrates a second shape of a first moisture-proof pattern and a second moisture-proof pattern in a display device according to exemplary embodiments of the present disclosure.

FIG. 17 illustrates a third shape of a first moisture-proof pattern and a second moisture-proof pattern in a display device according to exemplary embodiments of the present disclosure.

FIG. 18 illustrates a fourth shape of a first moisture-proof pattern and a second moisture-proof pattern in a display device according to exemplary embodiments of the present disclosure.

FIG. 19 illustrates a fifth shape of a first moisture-proof pattern and a second moisture-proof pattern in a display device according to exemplary embodiments of the present disclosure.

FIG. 20 illustrates a sixth shape of a first moisture-proof pattern and a second moisture-proof pattern in a display device according to exemplary embodiments of the present disclosure.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Hereinafter, some exemplary embodiments of the present disclosure will be described in detail with reference to exemplary drawings. In the following description of examples or embodiments of the present disclosure, reference will be made to the accompanying drawings in which it is shown by way of illustration specific exemplary examples or embodiments that can be implemented, and in which the same reference numerals and signs can be used to designate the same or like components even when they are shown in different accompanying drawings from one another. Further, in the following description of examples or exemplary embodiments of the present disclosure, detailed descriptions of well-known functions and components incorporated herein will be omitted when it is determined that the description may make the subject matter in some exemplary embodiments of the present disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” “a,” “b” may be used herein to describe elements of the present disclosure. Each of these terms is not used to define essence, order, sequence, or number of elements, etc., but is used merely to distinguish the corresponding element from other elements. For example, a first element could be termed a second element, and, similarly, a second element could be termed a first element, without departing from the scope of the present disclosure.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure. Further, in the following description of the present disclosure, when a detailed description of a known related art is determined to unnecessarily obscure the gist of the present disclosure, the detailed description thereof will be omitted or briefly given herein.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Hereinafter, various embodiments of the present disclosure will be described in detail with reference to the accompanying drawings.

This disclosure can be applied to the various display device. For example, the display device of this disclosure can be applied to various display device such as an organic light emitting display device, a liquid crystal display device, an electrophoretic display device, a quantum dot display device, a micro LED (Light Emitting Device) display device, and a mini LED display device. However, in the following description, the organic light emitting display device will be described as an example for convenience of explanation.

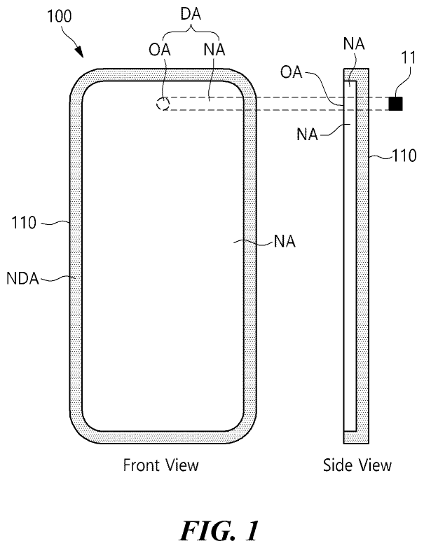

FIG. 1 illustrates a display device according to exemplary embodiments of the present disclosure.

Referring to FIG. 1, a display device 100 according to exemplary embodiments of the present disclosure may include a display panel 110 that displays an image and one or more optical electronic devices 11.

The display panel 110 may include a display area DA where an image is displayed and a non-display area NDA where an image is not displayed. In this case, the display area DA may be referred to as an active area.

A plurality of subpixels may be arranged in the display area DA, and various signal lines for driving the plurality of subpixels may be arranged.

The non-display area NDA may be an area outside the display area DA. Various signal lines may be arranged in the non-display area NDA, and various driving circuits may be connected thereto. At least a portion of the non-display area NDA may be bent so as not to be visible from the front, or may be covered by a case (not shown). The non-display area NDA may be also referred to as a bezel or an edge area.

In the display device 100 according to the embodiments of the present disclosure, one or more optical electronic devices 11 may be electronic components located below (e.g., opposite of the viewing surface) the display panel 110, without being limited thereto. Alternatively, optical electronic devices 11 may be integrally formed with the display panel 110.

Light may enter the front side (e.g., viewing surface) of the display panel 110, pass through the display panel 110, and be transmitted to one or more optical electronic devices 11 positioned below (e.g., opposite of the viewing surface) the display panel 110.

The one or more optical electronic devices 11 may be devices that receive light passing through the display panel 110 and perform a predetermined function according to the received light. For example, the one or more optical electronic devices 11 may include one or more of a photographing device such as a camera (or image sensor), a detection sensor such as a proximity sensor, and an illuminance sensor, etc.

In the display panel 110 according to the embodiments of the present disclosure, the display area DA may include a normal area NA and one or more optical areas OA.

Hereinafter, for convenience of descriptions related to shapes of the one or more optical areas OA, each of one or more optical areas OA is considered to have a circular shape. It should be, however, understood that the scope of the present disclosure includes examples where at least one of one or more optical areas OA have a shape other than a circular shape, such as an ellipse, a quadrangle, a hexagon, an octagon or the like, without being limited thereto.

The one or more optical areas OA may be areas overlapping with one or more optical electronic devices 11.

The display area DA may include a normal area NA and an optical area OA. Here, at least a portion of the optical area OA may overlap with an optical electronic device 11. FIG. 1 illustrates a front view and a side view of the example display device according to aspects of the present disclosure.

In the display device 100 according to the embodiments of the present disclosure, if the optical electronic device 11 that is not exposed to the outside and is hidden under the display panel 110 is a camera, the display device 100 according to the embodiments of the present disclosure may be referred to as a display to which an under-display camera (UDC) technology is applied.

Accordingly, in the case of the display device 100 according to the embodiments of the present disclosure, since a notch or camera hole for camera exposure does not need to be formed in the display panel 110, the area of the display area DA may not decrease.

Accordingly, since a notch or camera hole for camera exposure does not need to be formed in the display panel 110, the size of the bezel area can be reduced, and design constraints may be eliminated, thereby increasing the degree of freedom in design.

In the display device 100 according to the embodiments of the present disclosure, even though one or more optical electronic devices 11 are hidden and positioned behind the display panel 110, one or more optical electronic devices 11 is required to normally receive light and normally perform a corresponding function, but is not limited thereto. For example, one or more optical electronic devices 11 can receive light that has passed through the display panel 110.

In one or more aspects, the one or more optical electronic devices 11 that need to receive light may be exposed in the front surface (viewing surface) of the display panel 110 or the display device 100.

In addition, in the display device 100 according to the embodiments of the present disclosure, even though one or more optical electronic devices 11 are positioned hidden behind the display panel 110 and overlap with the display area DA, normal image display should be possible in one or more optical areas OA overlapping with one or more optical electronic devices 11 in the display area DA.

In one example, one or more optical electronic devices 11 may be, for example, a camera or a sensor, without being limited thereto. For example, the sensor may be a proximity sensor, an illuminance sensor, an infrared sensor, and/or the like. For example, the camera may be a camera lens, an image sensor, or a unit including at least one of the camera lens and the image sensor, but is not limited thereto.

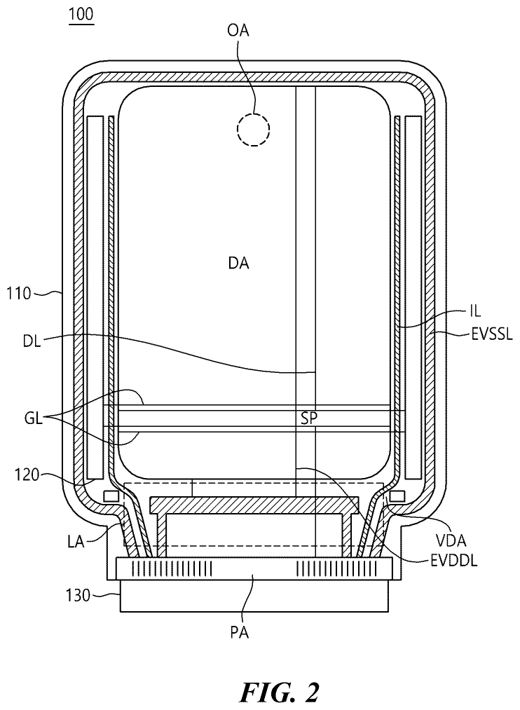

FIG. 2 is an exemplary plan view of a display device according to exemplary embodiments of the present disclosure.

Referring to FIG. 2, a display device 100 according to exemplary embodiments of the present disclosure may include at least one display area DA, and a plurality of subpixels SP may be disposed in the display area DA.

An optical area OA in which an optical electronic device is disposed may be included in the display area DA.

A non-display area NDA may be arranged around the display area DA. For example, a non-display area NDA may be arranged around the display area DA surrounding the display area DA. The non-display area NDA may surround the display area DA in a rectangular shape adjacent to one or more sides of the display area DA. However, the shape of the display area DA and the shape and arrangement of the non-display area NDA adjacent to the display area DA are not limited thereto.

A gate driving circuit 120 may be disposed in a side non-display area NDA of the display panel 110, and a data driving circuit 130 may be disposed in a lower non-display area NDA.

The data driving circuit 130 may be a circuit for driving the plurality of data lines DL, and can supply data signals to the plurality of data lines DL. The gate driving circuit 120 may be a circuit for driving a plurality of gate lines GL, and can supply gate signals to the plurality of gate lines GL.

In the display area DA, a plurality of subpixels SP connected to a plurality of data lines DL and a plurality of gate lines GL may be arranged at a location where a plurality of data lines DL and a plurality of gate lines GL intersect each other.

The non-display area NDA may include a pad area PA where the data driving circuit 130 and the display panel 110 come into contact and a link area LA.

The pads connected to the signal lines or the data driving circuit 130 may be disposed in the pad area PA. The pads for applying external signals to the panel, such as probe pads for lighting inspection and pads for bonding, may be located in the pad area PA.

In the link area LA, various connection lines and driving voltage lines (e.g., EVDDL, EVSSL) may be arranged between the pad area PA and the display area DA.

The driving voltage line may include a pixel high-potential voltage line EVDDL that applies a high-level pixel high-potential voltage EVDD to the subpixel SP and a pixel low-potential voltage line EVSSL that applies a low-level pixel low-potential voltage EVSS.

The pixel low-potential voltage line EVSSL may supply a common voltage to the subpixel SP, and may be arranged to surround a plurality of sides such as three sides of the display area DA between the gate driving circuit 120 and the edge of the display panel 110.

In addition, an initialization line IL for applying an initialization voltage to the subpixel SP may be arranged between the display area DA and the gate driving circuit 120.

The data driving circuit 130 may be mounted on a printed circuit board and connected to the display panel 110 through a pad area PA, or may be mounted in the form of a chip-on-panel in a link area LA between the pad area PA and the display area DA.

In one or more aspects, the data driving circuit 130 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique, without being limited thereto.

The data driving circuit 130 may include at least one source driving integrated circuit SDIC, and the gate driving circuit 120 may include at least one gate driving integrated circuit GDIC.

At least one source driving integrated circuit SDIC may receive image data and a source timing control signal from a timing controller. At least one source driving integrated circuit SDIC may convert image data into a data voltage in response to the source timing control signal and supply the data voltage to the display panel 110 through a data line DL.

The timing controller may be implemented in a separate component from the data driving circuit 130, or incorporated in the data driving circuit 130 and thus implemented in an integrated circuit, but is not limited thereto.

A subpixel SP of a display area DA may include a subpixel circuit which is connected to a gate line GL and a data line DL and operates in response to a data voltage. The subpixel circuit may be disposed to overlap with the data line DL or the gate line GL.

The subpixel SP may be implemented to include an organic light emitting element according to the configuration of the subpixel circuit. If the subpixel SP includes an organic light emitting element, the display panel 110 may be implemented in a top emission method, a bottom emission method, or a dual emission method, but is not limited thereto.

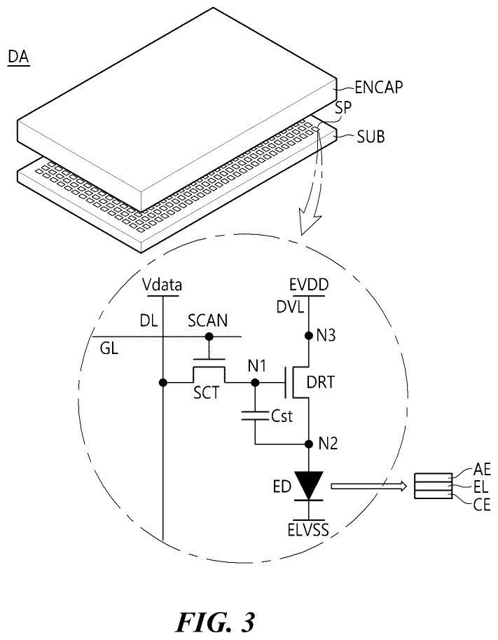

FIG. 3 illustrates an equivalent circuit of a subpixel in a display panel according to exemplary embodiments of the present disclosure as an example.

Referring to FIG. 3, in the display panel 110 according to the embodiments of the present disclosure, each of the subpixels SP arranged in the display area DA may include a light emitting element ED, a driving transistor DRT for driving the light emitting element ED, a scan transistor SCT for transmitting a data voltage Vdata to a first node N1 of the driving transistor DRT, and a storage capacitor Cst for maintaining a constant voltage during one frame, but is not limited thereto. More or less elements can be included.

The driving transistor DRT may be connected between a second node N2 and a third node N3. The driving transistor DRT may include a first node N1 to which a data voltage Vdata may be applied, a second node N2 electrically connected to the light emitting element ED, and a third node N3 to which a driving voltage ELVDD is applied from a driving voltage line DVL. In the driving transistor DRT, the first node N1 may be a gate node, the second node N2 may be a source node or a drain node, and the third node N3 may be a drain node or a source node.

The light emitting element ED may be disposed between the second node N2 and power line ELVSS supplied with the pixel low-potential voltage EVSS. The light emitting element ED may include an anode electrode AE, an emission layer EL, and a cathode electrode CE. The anode electrode AE may be a pixel electrode disposed in each subpixel SP and may be electrically connected to the second node N2 of the driving transistor DRT of each subpixel SP. The cathode electrode CE may be a common electrode arranged in common to a plurality of subpixels SP, and may be supplied with a pixel low-potential voltage EVSS.

For example, the emission layer EL may include one or more of a hole injection layer (HIL), a hole transmitting layer (HTL), an electron transmitting layer (ETL) and an electron injection layer (EIL), but the present disclosure is not limited thereto.

For example, the anode electrode AE may be a pixel electrode, and the cathode electrode CE may be a common electrode. Alternatively, the anode electrode AE may be a common electrode, and the cathode electrode CE may be a pixel electrode.

For example, the light emitting element ED may be an organic light-emitting diode (OLED), an inorganic light-emitting diode, or a quantum dot light emitting element. In this case, if the light emitting element ED is an organic light-emitting diode, the emission layer EL in the light emitting element ED may include an organic emission layer containing an organic material. Alternatively, if the light emitting element ED is an inorganic light-emitting diode, the emission layer EL in the light emitting element ED may include an inorganic emission layer containing an inorganic material.

The scan transistor SCT may be disposed between the first node N1 and the data line DL. The scan transistor SCT may be turned on and off by a scan signal SCAN, which is a gate signal applied through a gate line GL, and may be electrically connected between the first node N1 of the driving transistor DRT and the data line DL.

For example, when scan transistor SCT is turned on in response to scan signal SCAN, the data voltage Vdata may be applied to the first node N1 of the driving transistor DRT.

The storage capacitor Cst may be electrically connected between the first node N1 and the second node N2 of the driving transistor DRT.

Each subpixel SP may have a 2T-1C structure including two transistors (e.g., DRT and SCT) and one capacitor Cst as illustrated in FIG. 3, and may further include one or more transistors or one or more capacitors, depending on the case. For example, 3T1C, 4T1C, 5T1C, 3T2C, 4T2C, 5T2C, 6T2C, 7T1C, 7T2C, 8T2C structures, etc., are also possible. And more or less transistors and capacitors could be included.

The storage capacitor Cst may be an external capacitor intentionally designed outside the driving transistor DRT, rather than a parasitic capacitor (e.g., Cgs, Cgd) that may exist between the first node N1 and the second node N2 of the driving transistor DRT.

Each of the driving transistor DRT and the scan transistor SCT may be an n-type transistor or a p-type transistor.

Since the circuit elements (particularly, the light emitting element ED) in each subpixel SP are vulnerable to external moisture or oxygen, an encapsulation layer ENCAP may be disposed on the display panel 110 to prevent external moisture or oxygen from penetrating into the circuit elements (particularly, the light emitting element ED). The encapsulation layer ENCAP may be disposed in a form that covers the light emitting elements ED.

The encapsulation layer ENCAP may include a plurality of encapsulation layers including at least one inorganic encapsulation layer, and at least one organic encapsulation layer. For example, the encapsulation layer ENCAP may have a structure in which at least one organic encapsulation layer is disposed between inorganic encapsulation layers, but is not limited thereto.

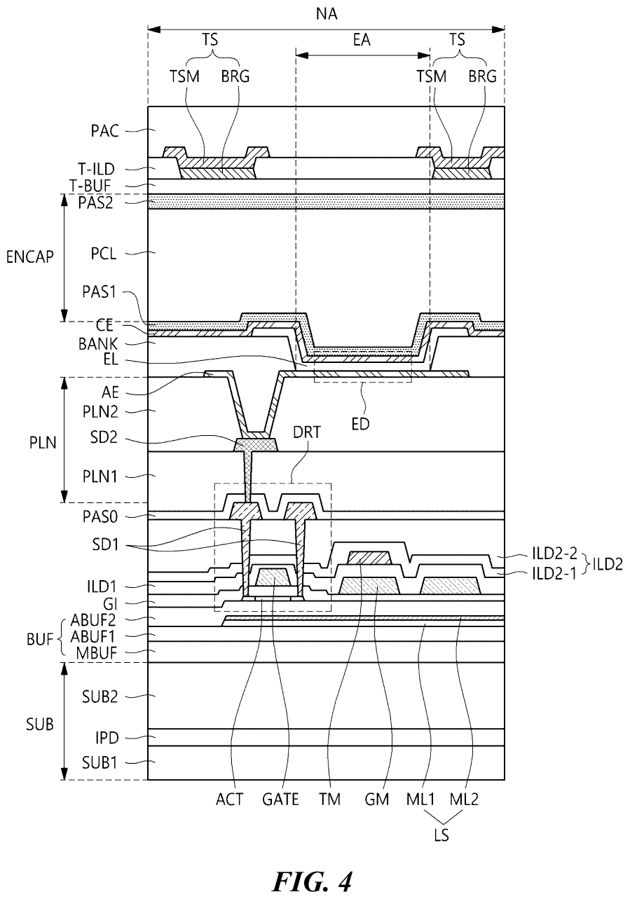

FIG. 4 illustrates an example of a cross-section of a normal area in a display area in a display panel according to exemplary embodiments of the present disclosure.

Here, it is illustrated the normal area NA excluding the optical area OA where the optical electronic device 11 is located.

Referring to FIG. 4, the display panel 110 according to exemplary embodiments of the present disclosure may include a substrate SUB, a driving transistor DRT, a planarization layer PLN, a light emitting element ED, an encapsulation layer ENCAP, and a touch layer.

The substrate SUB may include a first substrate SUB1, a substrate insulating film IPD, and a second substrate SUB2. The substrate insulating film IPD may be located between the first substrate SUB1 and the second substrate SUB2.

The moisture penetration may be prevented by configuring the substrate SUB with a first substrate SUB1, a substrate insulating film IPD, and a second substrate SUB2.

For example, the first substrate SUB1 and the second substrate SUB2 may be polyimide (PI) substrates. The first substrate SUB1 may be referred to as a primary PI substrate, and the second substrate SUB2 may be referred to as a secondary PI substrate.

Various patterns (e.g., ACT, SD1 and GATE), various insulating films (e.g., MBUF, ABUF1, ABUF2, GI, ILD1, ILD2 and PAS0), and various metal patterns (e.g., TM, GM, ML1 and ML2) for forming transistors such as a driving transistor DRT may be disposed on the substrate SUB.

A buffer layer BUF may be disposed on the substrate SUB. For example, multi-buffer layer MBUF of the buffer layer BUF may be disposed on the second substrate SUB2 of the substrate SUB, and a first active buffer layer ABUF1 of the buffer layer BUF may be disposed on the multi-buffer layer MBUF.

A plurality of metal layers may be disposed on the first active buffer layer ABUF1. For example, a first metal layer ML1 and a second metal layer ML2 may be disposed on the first active buffer layer ABUF1, but is not limited thereto. More or less metal layers may be disposed on the first active buffer layer ABUF1. Here, the first metal layer ML1 and the second metal layer ML2 may be a light shield layer LS for shielding the light.

A second active buffer layer ABUF2 of the buffer layer BUF may be disposed on the first metal layer ML1 and the second metal layer ML2. For example, the second active buffer layer ABUF2 may be disposed to cover the first metal layer ML1 and the second metal layer ML2 and a portion of the first active buffer layer ABUF1. A driving transistor DRT may be disposed on the second active buffer layer ABUF2. An active layer ACT of a driving transistor DRT may be disposed on the second active buffer layer ABUF2.

The multi-buffer layer MBUF, the first active buffer layer ABUF1, and the second active buffer layer ABUF2 may be collectively referred to as a buffer layer BUF.

A gate insulating film GI may be disposed while covering the active layer ACT.

The gate insulating film GI is an insulating layer for insulating the active layer ACT and the gate electrode GATE of a driving transistor DRT from each other, and may be composed of a single layer or multilayers of silicon oxide SiOx or silicon nitride SiNx, but is not limited thereto.

A gate electrode GATE of a driving transistor DRT may be disposed on the gate insulating film GI. In this case, at a position different from the formation position of the driving transistor DRT, a gate material layer GM may be disposed on the gate insulating film GI together with the gate electrode GATE of the driving transistor DRT.

A first interlayer insulating film ILD1 may be disposed while covering the gate electrode GATE and the gate material layer GM. A metal pattern TM may be disposed on the first interlayer insulating film ILD1. The metal pattern TM may be located at a position different from the formation position of the driving transistor DRT.

A second interlayer insulating film ILD2 may be disposed while covering the metal pattern TM on the first interlayer insulating film ILD1.

For example, the second interlayer insulating film ILD2 may be disposed on the metal pattern TM and a portion of the first interlayer insulating film ILD1.

Two first source-drain electrode patterns SD1 may be disposed on the second interlayer insulating film ILD2. One of the two first source-drain electrode patterns SD1 is a source node of a driving transistor DRT, and the other is a drain node of the driving transistor DRT.

One of the two first source-drain electrode patterns SD1 may be electrically connected to one side of the active layer ACT, and the other may be electrically connected to the other side of the active layer ACT. The two first source-drain electrode patterns SD1 may be electrically connected to one side and the other side of the active layer ACT, respectively, through contact holes passing through the second interlayer insulating film ILD2, the first interlayer insulating film ILD1, and the gate insulating film GI.

Meanwhile, the second interlayer insulating film ILD2 may include a 2-1 interlayer insulating film ILD2-1 and a 2-2 interlayer insulating film ILD2-2. The 2-1 interlayer insulating film ILD2-1 may be disposed while covering the metal pattern TM. The 2-1 interlayer insulating film ILD2-1 may be disposed to cover the metal pattern TM and a portion of the first interlayer insulating film ILD1 exposed by the metal pattern TM. The 2-2 interlayer insulating film ILD2-2 may be positioned on the 2-1 interlayer insulating film ILD2-1.

The first interlayer insulating film ILD1 and the second interlayer insulating film ILD2 may be formed of inorganic layers, but is not limited thereto.

A portion of the active layer ACT overlapping with the gate electrode GATE may be a channel area. One of the two first source-drain electrode patterns SD1 may be connected to one side of the channel area in the active layer ACT, and the other of the two first source-drain electrode patterns SD1 may be connected to the other side of the channel area in the active layer ACT.

A passivation layer PAS0 may be disposed while covering the two first source-drain electrode patterns SD1. A planarization layer PLN may be disposed on the passivation layer PAS0. For example, the passivation layer PAS0, which is a kind of dielectric (e.g., an inorganic dielectric), may be constituted by a single layer made of a silicon oxide (SiOx) film, a silicon nitride (SiNx) film, or a silicon oxynitride (SiOxNy) film or a multilayer film thereof, etc.

The planarization layer PLN may include a plurality planarization layers, such as a first planarization layer PLN1 and a second planarization layer PLN2, but is not limited thereto. More or less planarization layers can be included. The planarization layer PLN may be formed of an organic insulating material such as an acrylic resin.

For example, the planarization layer PLN may be formed of one or more materials of epoxy resin, phenolic resin, polyamides resin, unsaturated polyesters resin, polyphenylene resin, polyphenylene sulfides resin, and benzocyclobutene, but embodiments are not limited thereto.

The first planarization layer PLN1 may be disposed on the passivation layer PAS0.

A second source-drain electrode pattern SD2 may be disposed on the first planarization layer PLN1. The second source-drain electrode pattern SD2 may be connected to one of the two first source-drain electrode patterns SD1 (corresponding to the second node N2 of the driving transistor DRT in the subpixel SP of FIG. 3) through a contact hole passing through the first planarization layer PLN1.

The second planarization layer PLN2 may be disposed while covering the second source-drain electrode pattern SD2. A light emitting element ED may be disposed on the second planarization layer PLN2.

The light emitting element ED may include an anode electrode AE, an emission layer EL, and a cathode electrode CE. For example, the emission layer EL may be disposed between the anode electrode AE and the cathode electrode CE.

The anode electrode AE may be disposed on the second planarization layer PLN2. The anode electrode AE may be electrically connected to the second source-drain electrode pattern SD2 through a contact hole passing through the second planarization layer PLN2.

The bank BANK may be disposed while covering a part of the anode electrode AE. The bank BANK may be disposed to cover a part of the anode electrode AE and a part of the second planarization layer PLN2. A part of the bank BANK corresponding to the emission area EA of the subpixel SP may be opened or removed. For example, the bank BANK may be not disposed in the emission area EA of the subpixel SP.

A part of the anode electrode AE may be exposed to an opening (or open portion) of the bank BANK. For example, in the emission area EA of the subpixel SP, a part of the anode electrode AE may be exposed to an opening of the bank BANK.

An emission layer EL may be located on the side of the bank BANK and the opening (or open portion) of the bank BANK. All or part of the emission layer EL may be located between adjacent banks BANK. The emission layer EL may include an organic film.

In the opening of the bank BANK, the emission layer EL may be in contact with the anode electrode AE. A cathode electrode CE may be disposed on the emission layer EL. For example, the cathode electrode CE may be disposed on the emission layer EL and a part of the bank BANK.

An encapsulation layer ENCAP may be disposed on the light emitting element ED.

The encapsulation layer ENCAP may have a single-layer structure or a multi-layer structure. For example, the encapsulation layer ENCAP may include a first encapsulation layer PAS1, a second encapsulation layer PCL, and a third encapsulation layer PAS2, but is not limited thereto. For example, the second encapsulation layer PCL may be disposed between the first encapsulation layer PAS1 and the third encapsulation layer PAS2. More or less encapsulation layers can be included.

For example, the first encapsulation layer PAS1 and the third encapsulation layer PAS2 may be inorganic films, and the second encapsulation layer PCL may be an organic film. Among the first encapsulation layer PAS1, the second encapsulation layer PCL, and the third encapsulation layer PAS2, the second encapsulation layer PCL may be the thickest, but is not limited thereto. Accordingly, the second encapsulation layer PCL may function as a planarization layer.

The first encapsulation layer PAS1 may also be referred to as a first inorganic encapsulation layer, the second encapsulation layer PCL may also be referred to as an organic encapsulation layer, and the third encapsulation layer PAS2 may also be referred to as a second inorganic encapsulation layer.

The first encapsulation layer PAS1 may be disposed on the cathode electrode CE and may be disposed closest to the light emitting element ED. The first encapsulation layer PAS1 may be formed of an inorganic insulating material capable of low-temperature deposition. For example, the first encapsulation layer PAS1 may be silicon nitride (SiNx), silicon oxide (SiOx), silicon oxynitride (SiON), or aluminum oxide (Al2O3). Since the first encapsulation layer PAS1 is deposited in a low-temperature atmosphere, the first encapsulation layer PAS1 may prevent the emission layer EL including an organic material vulnerable to a high-temperature atmosphere from being damaged during the deposition process.

The second encapsulation layer PCL may be disposed on the first encapsulation layer PAS1. The second encapsulation layer PCL may be formed with a smaller area than the first encapsulation layer PAS1. In this case, the second encapsulation layer PCL may be formed to expose both ends of the first encapsulation layer PAS1. Among the first encapsulation layer PAS1, the second encapsulation layer PCL, and the third encapsulation layer PAS2, the second encapsulation layer PCL may be the thickest. The second encapsulating layer PCL may act as a buffer to relieve stress between each layer due to bending of the display device 100, and may also serve to enhance flattening performance.

For example, the second encapsulation layer PCL may be formed of an acrylic resin, an epoxy resin, a polyimide, polyethylene, or silicon oxycarbon (SiOC), and may be formed of an organic insulating material. For example, the second encapsulation layer PCL may be formed through an inkjet method.

The third encapsulation layer PAS2 may be formed on the second encapsulation layer PCL to cover the upper surface and side surfaces of each of the second encapsulation layer PCL and the first encapsulation layer PAS1. The third encapsulation layer PAS2 may minimize or block external moisture or oxygen from penetrating into the first encapsulation layer PAS1 and the second encapsulation layer PCL.

For example, the third encapsulation layer PAS2 may be formed of an inorganic insulating material such as silicon nitride (SiNx), silicon oxide (SiOx), silicon oxynitride (SiON), or aluminum oxide (Al₂O₃), but is not limited thereto.

Meanwhile, the display device 100 of the present disclosure may have a touch sensor TS formed on the encapsulation layer ENCAP to detect a touch of a user's finger or pen.

If the touch sensor TS is of a type built into the display panel 110, the touch sensor TS may be disposed on the encapsulation layer ENCAP. It will be described the touch sensor structure in detail as follows.

A touch buffer film T-BUF may be disposed on the encapsulation layer ENCAP. Specifically, the touch buffer film T-BUF may be disposed on the third encapsulation layer PAS2.

A touch sensor TS may be disposed on the touch buffer film T-BUF.

The touch sensor TS may include a touch sensor metal TSM and a bridge metal BRG positioned in different layers. The touch sensor metal TSM may be disposed on the bridge metal BRG and a portion of the touch interlayer insulating film T-ILD. The touch sensor metal TSM and the bridge metal BRG may be formed of a triple structure of Ti/Al/Ti.

A touch interlayer insulating film T-ILD may be disposed between the touch sensor metal TSM and the bridge metal BRG.

The touch interlayer insulating film T-ILD may be formed of an inorganic material such as silicon nitride (SiNx) or silicon oxide (SiOx). In this case, the touch interlayer insulating film T-ILD may be formed of an inorganic material such as silicon oxide (SiOx) to improve touch performance.

For example, the touch sensor TS may include a first touch sensor metal, a second touch sensor metal, and a third touch sensor metal that are positioned adjacent to each other.

If a third touch sensor metal is present between the first touch sensor metal and the second touch sensor metal, and the first touch sensor metal and the second touch sensor metal are to be electrically connected to each other, the first touch sensor metal and the second touch sensor metal may be electrically connected to each other through a bridge metal BRG in a different layer.

The bridge metal BRG may be insulated from the third touch sensor metal by a touch interlayer insulating film T-ILD.

When a touch sensor TS is formed on a display panel 110, a chemical solution (e.g., developer solution or etchant, etc.) used in the process or moisture may be generated from the outside.

Since the touch sensor TS is disposed on a touch buffer film T-BUF, the chemical solution or moisture may be prevented from penetrating into the emission layer EL including an organic substance during the manufacturing process of the touch sensor TS.

Accordingly, the touch buffer film T-BUF may prevent damage to the emission layer EL that is vulnerable to liquid or moisture.

The touch buffer film T-BUF may be formed at a low temperature (e.g., 100° C.) or lower, and may be formed of an organic insulating material having a low dielectric constant in order to prevent damage to the emission layer EL including an organic material vulnerable to high temperatures. For example, the touch buffer film T-BUF may be formed of an acrylic series, an epoxy series, or a siloxane series material.

If the display device 100 is bent, the encapsulation layer ENCAP may be damaged due to bending, and the touch sensor metal TSM located on the touch buffer film T-BUF may be broken. Even if the display device 100 is bent, the encapsulation layer ENCAP may be prevented from being damaged or the touch sensor metal TSM or bridge metal BRG may be prevented from being broken by the touch buffer film T-BUF having flattening performance using an organic insulating material.

A protection layer PAC can be arranged while covering the touch sensor TS. The protective layer PAC can be, for example, an organic insulating film. Specifically, the protective layer PAC may be configured to cover the touch sensor TS and the touch interlayer insulating film T-ILD.

In the display panel 110, the light emitting element ED may be damaged by moisture flowing into the emission layer EL through the through-hole where the optical electronic device 11 is disposed.

The display panel 110 of the present disclosure may block moisture from flowing in through the through-hole by forming a first moisture-proof pattern between the through-hole and the normal area NA.

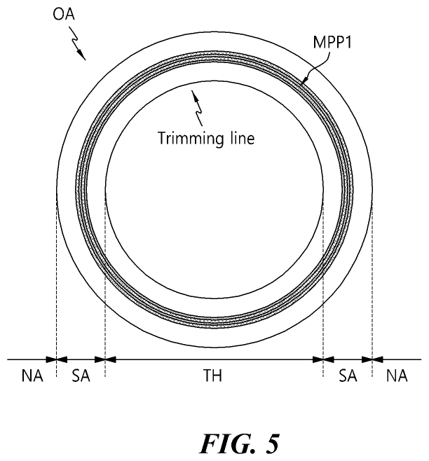

FIG. 5 illustrates an example of a planar structure of an optical area in a display device according to exemplary embodiments of the present disclosure.

Referring to FIG. 5, the display device 100 according to exemplary embodiments of the present disclosure may include an optical area OA within a display area DA. A plurality of pixels (not shown) may be disposed adjacent to the optical area OA.

The optical area OA may include a through-hole TH and a surrounding area SA located outside the through-hole TH. For example, subpixels for displaying images may not be located in the optical area OA.

A first moisture-proof pattern MPP1 may be located in the surrounding area SA to prevent moisture flowing in from the through-hole TH from being transferred to the normal area NA.

The through-hole TH may be formed by removing the substrate along a trimming line. The shape of the through-hole TH may be circular, but may have various shapes such as an oval, a square, a hexagon, or an octagon.

The first moisture-proof pattern MPP1 may include one or more patterns in the surrounding area SA to block a moisture-transfer path through which moisture flows in along the emission layer EL.

Meanwhile, an inner dam may be additionally formed between the first moisture-proof pattern MPP1 and the through-hole TH to distinguish the first moisture-proof pattern MPP1 and the through-hole TH.

An outer dam (not shown) may be disposed in the normal area NA on the outside of the first moisture-proof pattern MPP1. The outer dams may be disposed to prevent the encapsulation layer ENCAP from overflowing outside the normal area NA.

The first moisture-proof pattern MPP1 may have a closed curve shape that corresponds to the shape of the through-hole TH and surrounds the through-hole TH. The first moisture-proof pattern MPP1 may have a different closed curve shape from the through-hole TH, or may have a closed curve shape with the same shape but different sizes.

The shape of each dam may correspond to the shape of the through-hole TH, and have a closed curve shape surrounding the through-hole TH. For example, each dam and the through-hole TH may have different closed curve shapes, or have closed curve shapes with a same shape and different sizes. For example, each dam and the through-hole TH may have the same shape such as circle shapes with a common center and be arranged to be spaced apart from each other at a predefined interval. Each dam structure may have a stack of three layers disposed on the substrate SUB, without being limited thereto.

Here, it is exemplified a case in which the first moisture-proof pattern MPP1 and the through-hole TH have the same shape and are arranged at a certain interval.

The optical area OA may include the through-hole TH and the surrounding area SA surrounding the through-hole TH, and the normal area NA may be located on the outside of the surrounding area SA.

An optical electronic device 11 may be positioned in the through-hole TH below the display panel 110, and may overlap with at least a portion of the through-hole TH.

Each dam structure may have a stack of three layers disposed on the substrate SUB, without being limited thereto. For example, at least one of the dam structures may include a first layer formed of a portion of a planarization layer, a second layer formed of a portion of a bank BANK, and a third layer formed of a portion of a spacer (not shown), but is not limited thereto. The outer dams may be disposed to prevent the encapsulation layer ENCAP from overflowing outside the normal area NA.

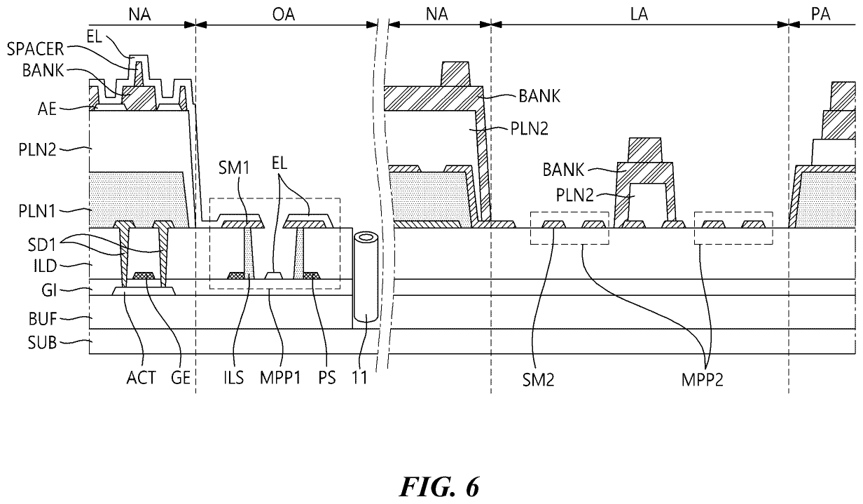

FIG. 6 is an overall cross-sectional view of a display device according to exemplary embodiments of the present disclosure.

Referring to FIG. 6, a display device 100 according to exemplary embodiments of the present disclosure may include a display area DA where an image is displayed and a non-display area NDA located outside the display area DA.

The display area DA may include a normal area NA and an optical area OA where the optical electronic device 11 is located.

The display device 100 of the present disclosure may include a first moisture-proof pattern MPP1 in the optical area OA to prevent moisture from flowing into the normal area NA from the optical area OA where the optical electronic device 11 is located. For example, the emission layer EL between the normal area NA and the optical electronic device 11 is disconnected by disposing the first moisture-proof patterns MPP1, so as to prevent moisture from flowing into the normal area NA from the optical area OA where the optical electronic device 11 is located.

In the convention display device, moisture flowing in from the optical electronic device 11 may be transferred to the normal area NA along the emission layer EL formed in the display area DA. Therefore, in the display device 100 of the present disclosure, the first moisture-proof pattern MPP1 may be formed as an emission layer disconnection structure that disconnects the emission layer EL between the normal area NA and the optical electronic device 11.

One or more first moisture-proof patterns MPP1 may be formed between the optical electronic device 11 and the normal area NA to disconnect the optical electronic device 11 from the normal area NA.

The first moisture-proof pattern MPP1 may include the sidewall structures and a recessed area between the sidewall structures (e.g., an interlayer insulating film ILD) while separating the sidewall structures. For example, the recessed area may be disposed between two sidewall structures.

The emission layer EL formed in the optical area OA may be physically divided into an emission layer located on the sidewall structures and an emission layer located in the recessed area by the recessed area of the first moisture-proof pattern MPP1. For example, the emission layers located on the sidewall structures are separated from each other by the recessed area. The emission layer located in the recessed area is disposed between the emission layers located on the sidewall structures.

Therefore, moisture flowing in through the optical electronic device 11 may be blocked from being transmitted to the normal area NA by the recessed area of the first moisture-proof pattern MPP1.

In this case, the first moisture-proof pattern MPP1 may include a moisture insulating layer ILS capable of preventing moisture from penetrating to the side while supporting the side of the recessed area, and a first shielding layer SM1 that prevents moisture from penetrating to the emission layer EL from the upper part of the recessed area. For example, the first shielding layer SM1 includes an emission layer disconnection structure on an upper portion of the recessed area.

The moisture insulating layer ILS may be formed with an undercut structure to insulate the side surface of the recessed area. The moisture insulating layer ILS may be formed of an organic insulating material, and may be formed of, for example, the same material as a first planarization layer PLN1 of the normal area NA, but is not limited thereto.

Although not shown here, a passivation layer may be formed between the interlayer insulating film ILD and the first planarization layer PLN1.

The moisture insulating layer ILS may further include a support structure PS for supporting the moisture insulating layer ILS from the outside. For example, the support structure PS is used for supporting the moisture insulating layer ILS from the outside on the gate insulating film GI. For example, the support structures PS may be disposed as a plurality of support structures PS which are disposed outside the moisture insulating layer ILS. In this case, the support structure PS may be formed of the same material as a gate electrode GATE of a transistor of the normal area NA. For example, the support structure PS may be formed of titanium (Ti).

The first shielding layer SM1 may be formed of the same material as a second source-drain electrode pattern SD2 constituting the transistor of the normal area NA. As one example, the first shielding layer SM1 may include a 1-1 metal layer and a 1-2 metal layer located on the 1-1 metal layer, and the 1-2 metal layer has a stepped structure from the 1-1 metal layer.

The first shielding layer SM1 may be formed of a laminated metal structure of titanium/aluminum/titanium (Ti/Al/Ti), but is not limited thereto.

In addition, the display device 100 of the present disclosure may include a second moisture-proof pattern MPP2 in a link area LA between a pad area PA to which the data driving circuit 130 is coupled and the normal area NA.

The second moisture-proof pattern MPP2 may include a plurality of second shielding layers SM2 formed on an interlayer insulating film ILD between the pad area PA and the normal area NA to block the transmission of moisture.

In addition, a dam may be included between the plurality of second shielding layers SM2 to prevent an organic material such as an encapsulation layer ENCAP from moving into the pad area PA during the manufacturing process of the display device 100.

The second moisture-proof pattern MPP2 formed in the link area LA may be formed with the same structure as the first moisture-proof pattern MPP1, or may be formed with a different structure.

If the second moisture-proof pattern MPP2 is formed with a different structure from the first moisture-proof pattern MPP1, the second moisture-proof pattern MPP2 may be formed with a second shielding layer SM2 in the form of an island spaced apart from each other on the interlayer insulating film ILD.

For example, the second moisture-proof pattern MPP2 may include a second shielding layer SM2 having a plurality of island structures spaced apart from each other in an area where a interlayer insulating film ILD protrudes upward.

In this case, the second shielding layer SM2 constituting the second moisture-proof pattern MPP2 may be formed by the same process as the second shielding layer SM2 constituting the first moisture-proof pattern MPP1 by using the same material. In this case, the plurality of second shielding layers SM2 may be formed by a laminated metal structure of titanium/aluminum/titanium (Ti/Al/Ti), but is not limited thereto.

Alternatively, the second shielding layer SM2 constituting the second moisture-proof pattern MPP2 may be formed by the different process from the second shielding layer SM2 constituting the first moisture-proof pattern MPP1 by using the different materials.

Meanwhile, if the first shielding layer SM1 and the second shielding layer SM2 are formed by a plurality of laminated structures, there may occur a phenomenon in which some metal is corroded by ions of a developing solution in a developing process for removing residual photoresist.

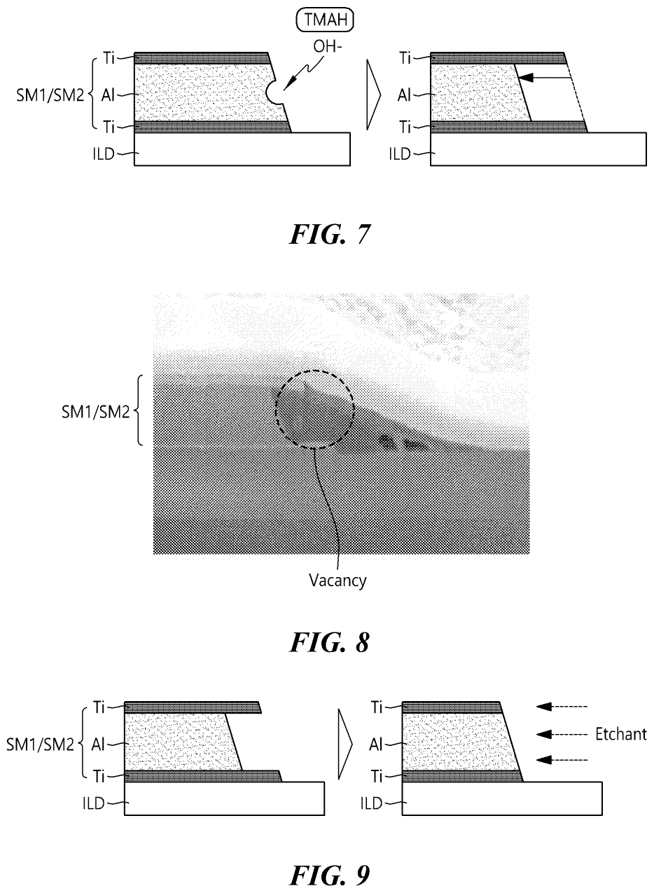

FIG. 7 illustrates a phenomenon in which a part of a moisture-proof pattern is corroded in a display device according to exemplary embodiments of the present disclosure, and FIG. 8 is a microscopic photograph illustrating a case in which a part of a moisture-proof pattern is corroded.

Referring to FIG. 6, the display device 100 according to the embodiments of the present disclosure may include a first moisture-proof pattern MPP1 formed in an optical area OA and a second moisture-proof pattern MPP2 formed in a link area LA to prevent moisture from entering.

For example, the first shielding layer SM1 may be formed in a trapezoidal shape, and the second shielding layer SM2 may be formed in a trapezoidal shape, but is not limited thereto.

In this case, the shielding layers SM1 and SM2 constituting the first moisture-proof pattern MPP1 and the second moisture-proof pattern MPP2 may be formed of the same material on an interlayer insulating film ILD, and may be formed of a laminated metal structure of, for example, titanium/aluminum/titanium (Ti/Al/Ti), but is not limited thereto.

In this case, referring to FIG. 7, after the first shielding layer SM1 and the second shielding layer SM2 are formed, in the developing process for removing the residual photoresist remaining on the upper portion of the first shielding layer SM1 and the second shielding layer SM2, a galvanic corrosion phenomenon may occur in which the aluminum constituting the first shielding layer SM1 and the second shielding layer SM2 is corroded by the developer.

Galvanic corrosion is a corrosion phenomenon in which, when two metals are exposed to a corrosive environment in a state of contact with each other, electrons move between the two metals due to the potential difference between the two metals, so that a corrosion rate of the metal with a relatively high noble potential decreases and a corrosion rate of the metal with a relatively low active potential increases.

If the first shielding layer SM1 and the second shielding layer SM2 are formed of a laminated metal structure of titanium/aluminum/titanium (Ti/Al/Ti), the corrosion rate of aluminum increases due to the hydroxide ion OH-of a developer such as tetramethylammonium hydroxide (TMAH).

As a result, a vacancy may be formed between the upper titanium (Ti) and the lower titanium (Ti) due to the corrosion of aluminum (Al), and the upper titanium (Ti) and the lower titanium (Ti) may form a tip structure that protrudes more than the aluminum (Al).

In this way, the vacancy and tip structure formed in the shielding layers SM1 and SM2 may provide a space for moisture to penetrate, which may cause a defect in which the shielding layers SM1 and SM2 cannot perform moisture-proof function.

The display device 100 of the present disclosure may prevent moisture from penetrating into a vacancy and reduce defects by removing a tip structure of a shielding layer constituting a moisture-proof pattern in a display device.

For example, the display device 100 of the present disclosure may prevent moisture from penetrating into a vacancy and reduce defects by removing the tip structure of the shielding layer SM1 and SM2 caused by galvanic corrosion using an etchant in the moisture-proof patterns MPP1 and MPP2 of the optical area OA and the link area LA.

FIG. 9 illustrates an example of a process of removing a tip structure of a shielding layer constituting a moisture-proof pattern in a display device according to exemplary embodiments of the present disclosure.

Referring to FIG. 6, a display device 100 according to exemplary embodiments of the present disclosure may include a first moisture-proof pattern MPP1 of an optical area OA and a second moisture-proof pattern MPP2 of a link area LA to prevent moisture from entering.

In this case, the shielding layers SM1 and SM2 constituting the first moisture-proof pattern MPP1 and the second moisture-proof pattern MPP2 may be formed of the same material on an interlayer insulating film ILD.

In this case, the first moisture-proof pattern MPP1 and the second moisture-proof pattern MPP2 may include shielding layers SM1 and SM2 made of a laminated metal structure of titanium/aluminum/titanium (Ti/Al/Ti), respectively.

The shielding layer SM1 and SM2 made of a laminated metal structure of titanium/aluminum/titanium (Ti/Al/Ti) may form a vacancy between the upper titanium (Ti) and the lower titanium (Ti) by galvanic corrosion during the development process for removing the photoresist, and the upper titanium (Ti) and the lower titanium (Ti) may form a tip structure that protrudes more than the aluminum (Al).

The vacancy and tip structure formed in the shielding layer SM1 and SM2 may provide a space for moisture to penetrate, which may cause a defect in which the shielding layer SM1 and SM2 cannot prevent moisture from entering.

The display device 100 of the present disclosure may prevent moisture from penetrating into a vacancy and reduce defects by removing a tip structure of a shielding layer constituting a moisture-proof pattern in a display device.

Therefore, the display device 100 of the present disclosure can prevent moisture from penetrating into the vacancy and reduce defects by removing the tip structure of the shielding layer SM1 and SM2 using an etchant after the development process.

The etchant for removing the tip structure of the shielding layer SM1 and SM2 may include a buffered oxide etchant (BOE) or a silicon-based oxide etching solution used in wet etching, but is not limited thereto.

The tip structure of the shielding layer SM1 and SM2 is removed, so that the shielding layers SM1 and SM2 constituting the first moisture-proof pattern MPP1 and the second moisture-proof pattern MPP2 may be formed in a trapezoidal shape as a whole, with a first metal layer (Ti), a second metal layer (Al), and a third metal layer (Ti), respectively.

For example, the first shielding layer SM1 may include: a 1-1 metal layer; a 1-2 metal layer located on the 1-1 metal layer; and a 1-3 metal layer located on the 1-2 metal layer. For example, the second shielding layer SM2 may include a 2-1 metal layer; a 2-2 metal layer located on the 2-1 metal layer; and a 2-3 metal layer located on the 2-2 metal layer, but is not limited thereto.

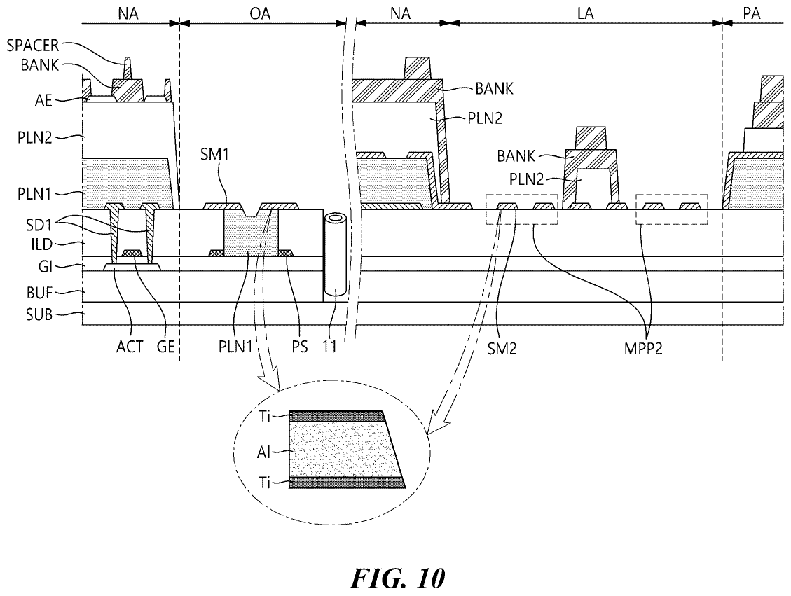

FIGS. 10 to 14 are drawings illustrating an example of a process of forming a first moisture-proof pattern in an optical area and a second moisture-proof pattern in a link area in a display device according to exemplary embodiments of the present disclosure.

FIGS. 10 to 14 are drawings sequentially showing a process of forming a first moisture-proof pattern MPP1 of an optical area OA and a second moisture-proof pattern MPP2 of a link area LA, and parts overlapping with those described in FIGS. 4 and 6 may be omitted.

First, referring to FIG. 10, a display device 100 according to exemplary embodiments of the present disclosure may form a recessed area in a portion of an interlayer insulating film ILD of an optical area OA where a first moisture-proof pattern MPP1 is to be formed, and deposit a first planarization layer PLN1 so as to fill the recessed area.

After the first planarization layer PLN1 is formed, the first shielding layer SM1 of the optical area OA and the second shielding layer SM2 of the link area LA may be formed using a second source-drain electrode pattern SD2.

The first shielding layer SM1 and the second shielding layer SM2 may be formed as a laminated metal structure of titanium/aluminum/titanium (Ti/Al/Ti), but is not limited thereto.

Next, the second planarization layer PLN2 may be formed in the normal area NA where the subpixel SP is formed, and the anode electrode AE and bank BANK defining the light emitting element may be sequentially formed. For example, the second planarization layer PLN2 may be formed on the first planarization layer PLN1 in the normal area NA where the subpixel SP is formed.

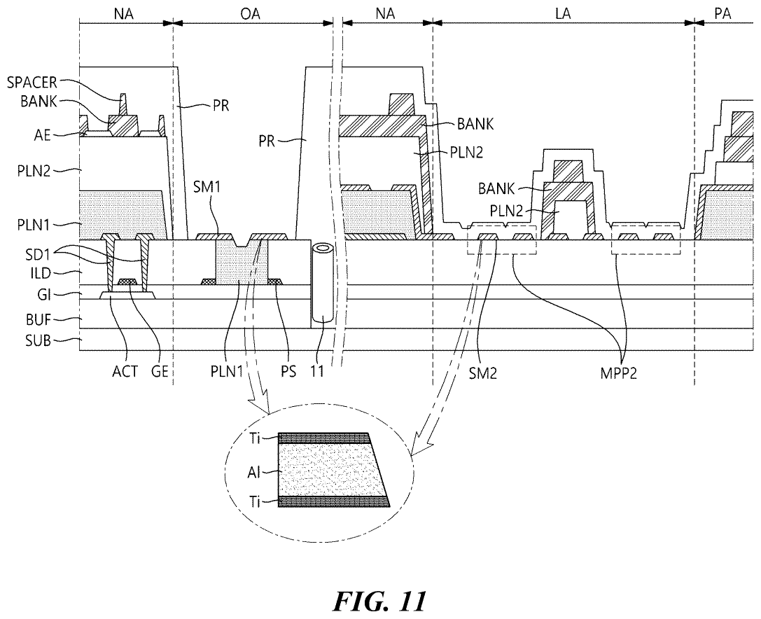

Then, as shown in FIG. 11, in order to form a first moisture-proof pattern MPP1, a photoresist PR may be applied to the remaining area except the optical area OA. For example, the optical area OA may be exposed by the photoresist PR.

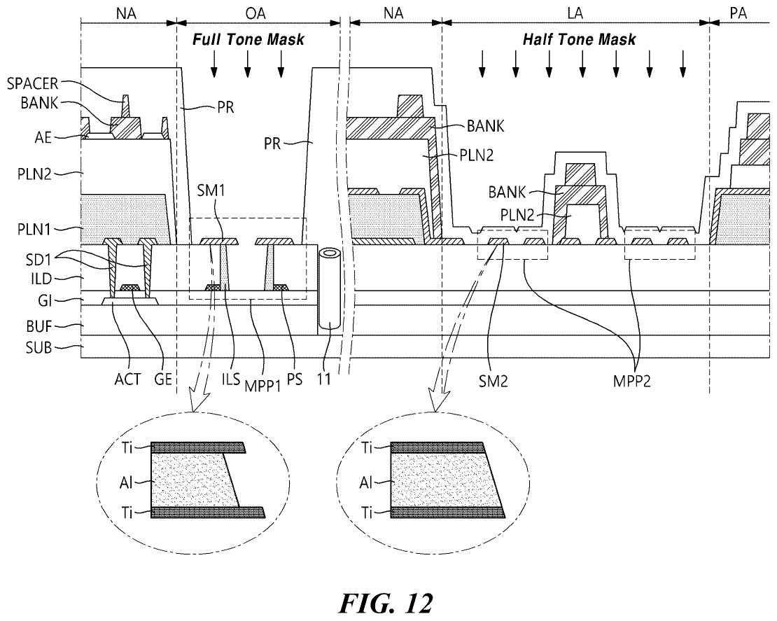

With the photoresist PR applied, a full tone mask may be placed in the optical area OA and a half tone mask may be placed in the link area LA as shown in FIG. 12 to form the first moisture-proof pattern MPP1.

Since the first moisture-proof pattern MPP1 includes a moisture insulating layer ILS corresponding to the thickness of the interlayer insulating film ILD, it is required to etch the first planarization layer PLN1 corresponding to the thickness of the interlayer insulating film ILD. Therefore, the etching depth of the first planarization layer PLN1 may be controlled by placing a full tone mask in the optical area OA.

In this process, galvanic corrosion may occur in the first shielding layer SM1 forming the first moisture-proof pattern MPP1, so that a 1-1 metal (Ti) and a 1-3 metal (Ti) of the first shielding layer SM1 may protrude and a vacancy may be generated in a 1-2 metal (Al) in the middle.

In this case, the tip structure of the shielding layer SM1 may be removed by using an etchant to prevent moisture from penetrating into the vacancy generated in a 1-2 metal (Al) in the middle and reduce defects.

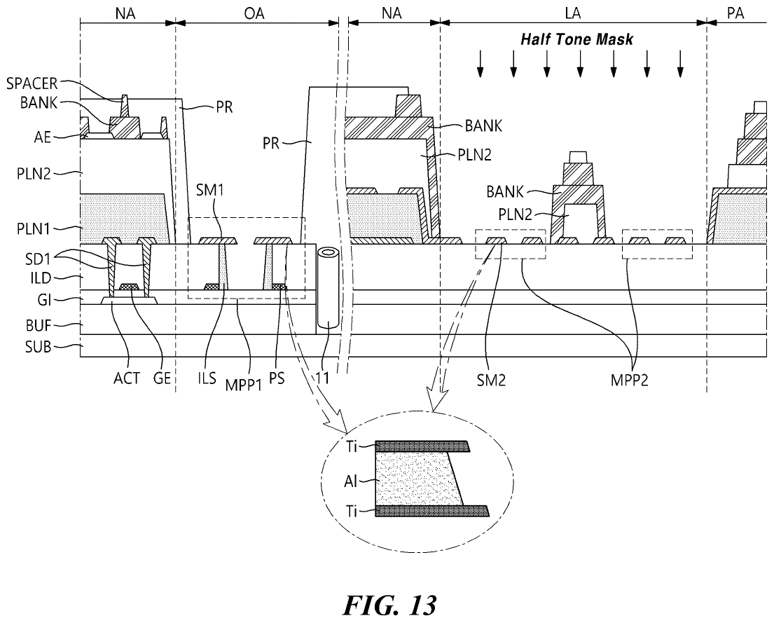

After forming the first moisture-proof pattern MPP1, the photoresist PR remaining in the link area LA may be removed as shown in FIG. 13 in order to form the second moisture-proof pattern MPP2.

In this process, galvanic corrosion may also occur in the second shielding layer SM2 forming the second moisture-proof pattern MPP2, so that a 2-1 metal layer (Ti) and a 2-3 metal (Ti) of the second shielding layer SM2 may protrude and a vacancy may be formed in a 2-2 metal (Al) in the middle.

In this case, the tip structure of the second shielding layer SM2 may be removed by using an etchant to prevent moisture from penetrating into the vacancy generated in a 2-2 metal (Al) in the middle and reduce defects.

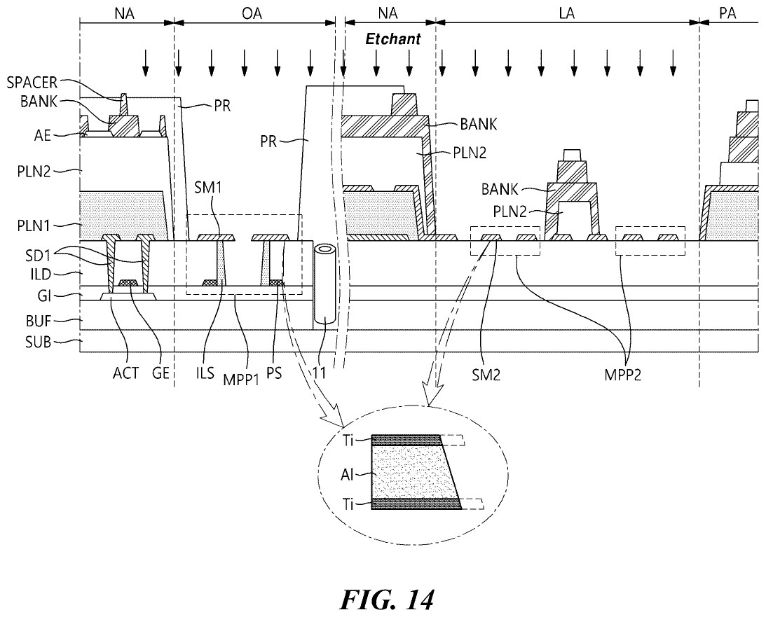

In this state, as shown in FIG. 14, the tip structure of the first shielding layer SM1 of the optical area OA and the second shielding layer SM2 of the link area LA may be removed using an etchant to prevent moisture from penetrating into the vacancy and reduce defects.

As a result, the vacancy of the shielding layers SM1 and SM2 constituting the first moisture-proof pattern MPP1 and the second moisture-proof pattern MPP2 may be removed, thereby preventing moisture from penetrating and reducing defects.

In this case, in the process of removing the tip structure of the first shielding layer SM1 of the optical area OA and the second shielding layer SM2 of the link area LA, the shape of the first moisture-proof pattern MPP1 of the optical area OA and the second moisture-proof pattern MPP2 of the link area LA may vary depending on the position of the mask and the usage time of the etchant.

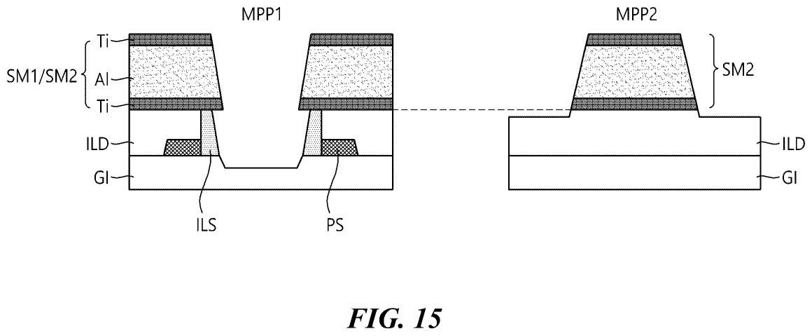

FIG. 15 illustrates a first shape of the first moisture-proof pattern and the second moisture-proof pattern in the display device according to exemplary embodiments of the present disclosure.

Referring to FIG. 15, in the display device 100 according to the embodiments of the present disclosure, the first moisture-proof pattern MPP1 formed in the optical area OA may include a first shielding layer SM1 positioned on both sides of the recessed area of the interlayer insulating film ILD and a moisture insulating layer ILS formed in an undercut shape on the inner sidewall of the recessed area. In addition, the moisture insulating layer ILS may further include a support structure PS for supporting the moisture insulating layer ILS from the outside. For example, the first shielding layer SM1 may include an emission layer disconnection structure on an upper portion of the recessed area.

Since the tip structure of the first shielding layer SM1 may be removed by using an etchant in the display device 100 of the present disclosure, the first shielding layer SM1 may be formed in an overall trapezoidal shape.

For example, the 1-1 metal layer (Ti), the 1-2 metal layer (Al), and the 1-3 metal layer (Ti) constituting the first shielding layer SM1 may be formed in an overall trapezoidal shape.

In this case, in the process of removing the tip structure of the first shielding layer SM1 using an etchant, the depth of the recessed area of the first moisture-proof pattern MPP1 may increase. In this way, the depth of the recessed area of the first moisture-proof pattern MPP1 increases, so that the disconnection effect of the emission layer EL located on the first shielding layer SM1 and the emission layer EL located inside the recessed area may increase, thereby enhancing the moisture-proof function.

In addition, the second moisture-proof pattern MPP2 formed in the link area LA may include a second shielding layer SM2 formed on an interlayer insulating film ILD.

Since the tip structure of the second shielding layer SM2 of the display device 100 of the present disclosure may be removed by using an etchant, the second shielding layer SM2 may be formed in a trapezoidal shape as a whole.

For example, the 2-1 metal layer (Ti), the 2-2 metal layer (Al), and the 2-3 metal layer (Ti) constituting the second shielding layer SM2 may be formed in a trapezoidal shape as a whole.

In this case, in the process of forming the recessed area of the first moisture-proof pattern MPP1, the interlayer insulating film ILD located in the surrounding area of the second moisture-proof pattern MPP2 can be etched, so the second moisture-proof pattern MPP2 may be located in the area where the interlayer insulating film ILD protrudes upward.

As a result, a height between a rear surface and an upper surface of the interlayer insulating film ILD where the first moisture-proof pattern MPP1 is located may be greater than a height between a rear surface and an upper surface of the interlayer insulating film ILD where the second moisture-proof pattern MPP2 is located.

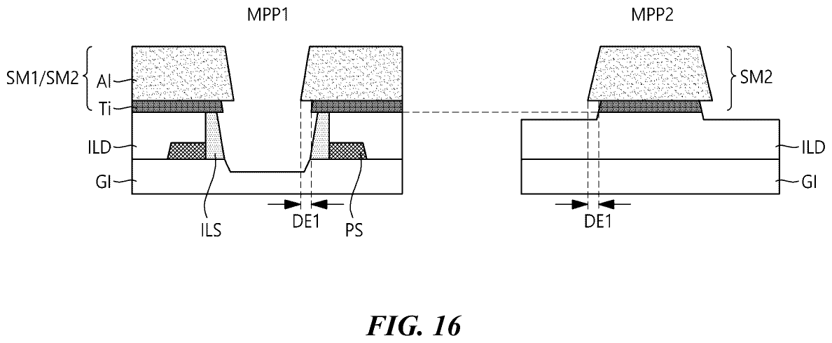

FIG. 16 illustrates a second shape of the first moisture-proof pattern and the second moisture-proof pattern in the display device according to the embodiments of the present disclosure.

Referring to FIG. 16, in the display device 100 according to the embodiments of the present disclosure, the upper metal layer (e.g., the 1-3 metal layer and the 2-3 metal layer) of the shielding layers SM1 and SM2 may be removed by increasing the etchant treatment time during the process of removing the tip structure of the shielding layer SM1 and SM2 of the first moisture-proof pattern MPP1 and the second moisture-proof pattern MPP2.

In this case, the first shielding layer SM1 constituting the first moisture-proof pattern MPP1 may be formed by the 1-1 metal layer (Ti) at the bottom and the 1-2 metal layer (Al) at the top by removing the upper 1-3 metal layer (Ti). However, since the 1-1 metal layer (Ti) is also partially etched due to the increase in the etchant treatment time in the process of removing the tip structure of the first shielding layer SM1, the 1-1 metal layer (Ti) and the 1-2 metal layer (Al) may be formed to have a stepped structure with a first stepped distance DE1.

Similarly, the second shielding layer SM2 constituting the second moisture-proof pattern MPP2 may be formed by the 2-1 metal layer (Ti) at the bottom and the 2-2 metal layer (Al) at the top by removing the upper 2-3 metal layer (Ti). In addition, since the 2-1 metal layer (Ti) is also partially etched due to the increase in the etchant treatment time in the process of removing the tip structure of the second shielding layer SM2, the 2-1 metal layer (Ti) and the 2-2 metal layer (Al) may be formed as a stepped structure having a first stepped distance DE1.

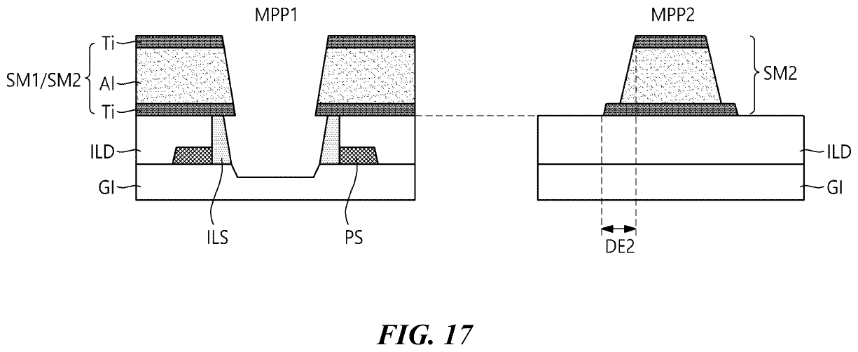

FIG. 17 illustrates a third shape of the first moisture-proof pattern and the second moisture-proof pattern in the display device according to the embodiments of the present disclosure.

Referring to FIG. 17, in the display device 100 according to the embodiments of the present disclosure, the first moisture-proof pattern MPP1 formed in the optical area OA may include the first shielding layer SM1 located on both sides of the recessed area of the interlayer insulating film ILD and the moisture insulating layer ILS formed in an undercut shape on the inner sidewall of the recessed area. In addition, the moisture insulating layer ILS may further include a support structure PS for supporting the moisture insulating layer ILS from the outside. For example, the first shielding layer SM1 may include an emission layer disconnection structure on an upper portion of the recessed area.

Since the tip structure of the first shielding layer SM1 may be removed by using an etchant in the display device 100 of the present disclosure, the first shielding layer SM1 may be formed in a trapezoidal shape as a whole.

For example, the 1-1 metal layer (Ti), the 1-2 metal layer (Al), and the 1-3 metal layer (Ti) constituting the first shielding layer SM1 may be formed in a trapezoidal shape as a whole.

In this case, the depth of the recessed area of the first moisture-proof pattern MPP1 may increase in the process of removing the tip structure of the first shielding layer SM1 using an etchant. The depth of the recessed area of the first moisture-proof pattern MPP1 can increase, so that the disconnection effect of the emission layer EL located on the upper side of the first shielding layer SM1 and the emission layer EL located inside the recessed area may also increase, thereby strengthening the moisture-proof function.

In addition, the second moisture-proof pattern MPP2 formed in the link area LA may include a second shielding layer SM2 formed on the interlayer insulating film ILD.

The display device 100 of the present disclosure may remove the tip structure of the second shielding layer SM2 using an etchant to remove the vacancy caused by galvanic corrosion.

Since the tip structure of the second shielding layer SM2 of the display device 100 of the present disclosure may be removed by using an etchant, the second shielding layer SM2 may be formed in a trapezoidal shape as a whole.

In this case, by forming the mask so that there is a second stepped distance DE2 between the 2-1 metal layer (Ti) and the 2-3 metal layer (Ti) constituting the second shielding layer SM2, the length of the lower 2-1 metal layer (Ti) can be formed to protrude more than the upper 2-2 metal layer (Al).

Accordingly, while the 2-1 metal layer (Ti), the 2-2 metal layer (Al), and the 2-3 metal layer (Ti) constituting the second shielding layer SM2 are formed in an overall trapezoidal shape, the lower 2-1 metal layer (Ti) may be formed in a wide structure.

If the upper 2-3 metal layer (Ti) is formed widely, moisture may flow in due to the vacancy underneath. However, if the lower 2-1 metal layer (Ti) is formed widely, moisture may be prevented from flowing in since a vacancy is not formed due to the upper laminated structure covering the second moisture-proof pattern MPP2.

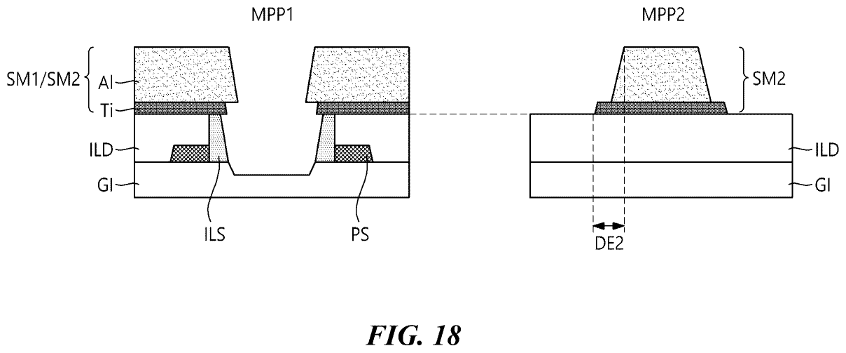

FIG. 18 illustrates a fourth shape of the first moisture-proof pattern and the second moisture-proof pattern in the display device according to exemplary embodiments of the present disclosure.

Referring to FIG. 18, the display device 100 according to the embodiments of the present disclosure may remove the upper metal layer (e.g., the 1-3 metal layer and the 2-3 metal layer, Ti) of the shielding layer SM1 and SM2 by increasing the etchant treatment time during the process of removing the tip structure of the shielding layer SM1 and SM2 of the first moisture-proof pattern MPP1 and the second moisture-proof pattern MPP2.

In this case, the first shielding layer SM1 constituting the first moisture-proof pattern MPP1 may be formed of the 1-1 metal layer (Ti) at the bottom and the 1-2 metal layer (Al) at the top by removing the upper 1-3 metal layer (Ti). However, since the 1-1 metal layer (Ti) is also partially etched due to the increase in the etchant treatment time in the process of removing the tip structure of the first shielding layer SM1, the 1-1 metal layer (Ti) and the 1-2 metal layer (Al) may be formed in a stepped structure.

Similarly, the second shielding layer SM2 constituting the second moisture-proof pattern MPP2 may be formed by the 2-1 metal layer (Ti) at the bottom and the 2-2 metal layer (Al) at the top by removing the upper 2-3 metal layer (Ti). In addition, the 2-1 metal layer (Ti) may also be partially etched due to the increase in the etchant treatment time in the process of removing the tip structure of the second shielding layer SM2, the 2-1 metal layer (Ti) and the 2-2 metal layer (Al) may be formed as a stepped structure having a Second stepped distance DE2.

If the lower 2-1 metal layer (Ti) is formed widely, moisture may be prevented from flowing in since a vacancy is not formed due to the upper laminated structure covering the second moisture-proof pattern MPP2.

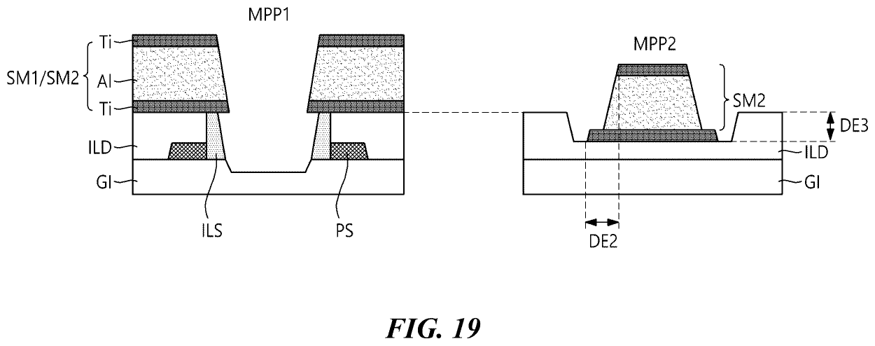

FIG. 19 illustrates a fifth shape of the first moisture-proof pattern and the second moisture-proof pattern in a display device according to exemplary embodiments of the present disclosure.

Referring to FIG. 19, in the display device 100 according to the embodiments of the present disclosure, the first moisture-proof pattern MPP1 formed in the optical area OA may include a first shielding layer SM1 positioned on both sides of the recessed area of the interlayer insulating film ILD and a moisture insulating layer ILS formed in an undercut shape on the inner side wall of the recessed area. In addition, the moisture insulating layer ILS may further include a support structure PS for supporting the moisture insulating layer ILS from the outside. For example, the first shielding layer SM1 may include an emission layer disconnection structure on an upper portion of the recessed area.

Since the tip structure of the first shielding layer SM1 can be removed by using an etchant in the display device 100 of the present disclosure, the first shielding layer SM1 may be formed in a trapezoidal shape as a whole.

For example, the 1-1 metal layer (Ti), the 1-2 metal layer (Al), and the 1-3 metal layer (Ti) constituting the first shielding layer SM1 may be formed in a trapezoidal shape as a whole.

In this case, in the process of removing the tip structure of the first shielding layer SM1 using an etchant, the depth of the recessed area of the first moisture-proof pattern MPP1 can increase. Accordingly, as the depth of the recessed area of the first moisture-proof pattern MPP1 increases, it is possible to increase the disconnection effect of the emission layer EL located on the first shielding layer SM1 and the emission layer EL located inside the recessed area, thereby enhancing the moisture-proof function.

In addition, the second moisture-proof pattern MPP2 formed in the link area LA may include a second shielding layer SM2 formed on the interlayer insulating film ILD.

In this case, a groove having a third stepped distance DE3 may be formed in the interlayer insulating film ILD of the link area LA, and the second moisture-proof pattern MPP2 may be formed inside the groove.

In this way, if the second moisture-proof pattern MPP2 is formed inside the groove of the interlayer insulating film ILD, the height of the second moisture-proof pattern MPP2 may be lowered, thereby facilitating the upper flattening operation of the link area LA.

In this case, during the process of forming the recessed area of the first moisture-proof pattern MPP1, the interlayer insulating film ILD in the area where the second moisture-proof pattern MPP2 is located may be etched, so that the second moisture-proof pattern MPP2 may be located in the recessed area of the interlayer insulating film ILD.

In this case, the height between a rear surface and an upper surface of the interlayer insulating film ILD where the first moisture-proof pattern MPP1 is positioned may be the same as the height between a rear surface and an upper surface of the interlayer insulating film ILD where the second moisture-proof pattern MPP2 is positioned.

In a state where the second moisture-proof pattern MPP2 is formed inside the groove of the interlayer insulating film ILD, the display device 100 of the present disclosure may remove the tip structure of the second shielding layer SM2 using an etchant to remove the vacancy caused by galvanic corrosion, the second shielding layer SM2 may be formed in an overall trapezoidal shape.

Accordingly, the 2-1 metal layer (Ti), the 2-2 metal layer (Al), and the 2-3 metal layer (Ti) constituting the second shielding layer SM2 may be formed in an overall trapezoidal shape.

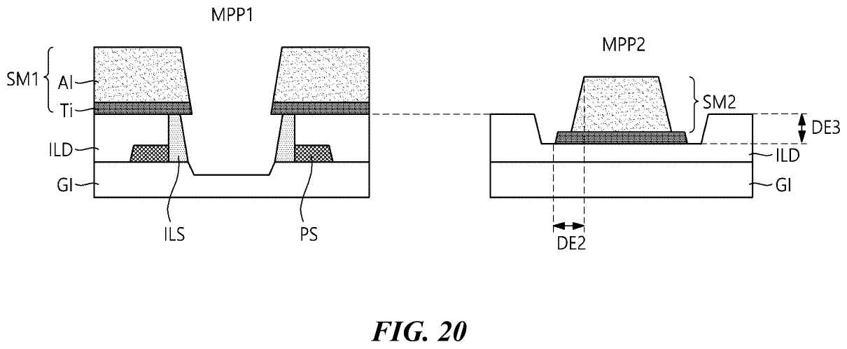

FIG. 20 illustrates a sixth shape of the first moisture-proof pattern and the second moisture-proof pattern in the display device according to exemplary embodiments of the present disclosure.

Referring to FIG. 20, the display device 100 according to the embodiments of the present disclosure may remove the upper metal layer (e.g., the 1-3 metal layer and the 2-3 metal layer, Ti) of the shielding layer SM1 and SM2 by increasing the etchant treatment time during the process of removing the tip structure of the shielding layer SM1 and SM2 of the first moisture-proof pattern MPP1 and the second moisture-proof pattern MPP2.

In this case, the first shielding layer SM1 constituting the first moisture-proof pattern MPP1 may be formed of the 1-1 metal layer (Ti) at the bottom and the 1-2 metal layer (Al) at the top by removing the upper 1-3 metal layer (Ti). However, since the 1-1 metal layer (Ti) is also partially etched due to the increase in the etchant treatment time in the process of removing the tip structure of the first shielding layer SM1, the 1-1 metal layer (Ti) and the 1-2 metal layer (Al) may be formed as a stepped structure.

Similarly, the second shielding layer SM2 constituting the second moisture-proof pattern MPP2 may be formed by the 2-1 metal layer (Ti) on the lower side and the 2-2 metal layer (Al) on the upper side by removing the upper 2-3 metal layer (Ti). In addition, the 2-1 metal layer (Ti) may also be partially etched due to the increase in the etchant treatment time in the process of removing the tip structure of the second shielding layer SM2, the 2-1 metal layer (Ti) and the 2-2 metal layer (Al) may be formed as a stepped structure having a Second stepped distance DE2.

The display device and display panel according to the embodiments of the present disclosure may be described as follows.

A display device according to the embodiments of the present disclosure may include a display panel including a normal area where a plurality of subpixels are disposed, an optical area where an optical electronic device is located, and a link area where a driving signal line extends from a pad area, and a driving circuit configured to transmit a driving signal through the driving signal line. In this case, the optical area may include a first moisture-proof pattern formed between the optical electronic device and the normal area, and the link area may include a second moisture-proof pattern formed between the pad area and the normal area.

The first moisture-proof pattern may include a moisture insulating layer supporting a side in a recessed area of an interlayer insulating film, and a first shielding layer including an emission layer disconnection structure on an upper portion of the recessed area.

The moisture insulating layer may be formed of the same material as a planarization layer of the normal area.

The first moisture-proof pattern may further include a support structure supporting the moisture insulating layer from the outside.

The support structure may be formed of the same material as a gate electrode constituting a transistor of the normal area.

The first shielding layer may be formed of the same material as a second source-drain electrode pattern constituting the transistor of the normal area.

The first shielding layer may include a 1-1 metal layer, a 1-2 metal layer located on the 1-1 metal layer, and a 1-3 metal layer located on the 1-2 metal layer, wherein the first shielding layer may be formed in a trapezoidal shape.

The first shielding layer may include a 1-1 metal layer, and a 1-2 metal layer located on the 1-1 metal layer, and having a stepped structure from the 1-1 metal layer, wherein the first shielding layer may be formed in a trapezoidal shape.

The second moisture-proof pattern may include a second shielding layer having a plurality of island structures spaced apart from each other on an interlayer insulating film.

The second shielding layer may be provided as a plurality of second shielding layers, and a dam is included between the plurality of second shielding layers.

The second shielding layer may include a 2-1 metal layer, a 2-2 metal layer located on the 2-1 metal layer, and a 2-3 metal layer located on the 2-2 metal layer, wherein the second shielding layer may be formed in a trapezoidal shape.

The 2-1 metal layer is formed so as to protrude from a side of the 2-2 metal layer.

The second shielding layer may include a 2-1 metal layer, and a 2-2 metal layer located on the 2-1 metal layer, and having a stepped structure from the 2-1 metal layer, wherein the second shielding layer may be formed in a trapezoidal shape.

The 2-1 metal layer may be formed so as to protrude from a side of the 2-2 metal layer.

The second moisture-proof pattern may include a second shielding layer having a plurality of island structures spaced apart from each other within a groove formed on an interlayer insulating film.

The first shielding layer may include: a 1-1 metal layer; a 1-2 metal layer located on the 1-1 metal layer; and a 1-3 metal layer located on the 1-2 metal layer, wherein the first shielding layer is formed in a trapezoidal shape.

The first shielding layer may include: a 1-1 metal layer; and a 1-2 metal layer located on the 1-1 metal layer, and having a stepped structure from the 1-1 metal layer, wherein the first shielding layer is formed in a trapezoidal shape.

The second shielding layer may include a 2-1 metal layer, a 2-2 metal layer located on the 2-1 metal layer, and a 2-3 metal layer located on the 2-2 metal layer, wherein the second shielding layer may be formed in a trapezoidal shape.

The second shielding layer may include a 2-1 metal layer, and a 2-2 metal layer located on the 2-1 metal layer, and having a stepped structure from the 2-1 metal layer. The second shielding layer may be formed in a trapezoidal shape.

A display panel according to exemplary embodiments of the present disclosure may include a normal area where a plurality of subpixels are disposed, an optical area where an optical electronic device is located, and a link area where a driving signal line extends from a pad area to which a driving circuit is connected. The optical area may include a first moisture-proof pattern formed between the optical electronic device and the normal area, and the link area may include a second moisture-proof pattern formed between the pad area and the normal area.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel including a normal area where a plurality of subpixels are disposed, an optical area where an optical electronic device is located, a pad area, and a link area where a driving signal line extends from the pad area;
a driving circuit configured to supply a driving signal through the driving signal line;
a first moisture-proof pattern disposed in the optical area between the optical electronic device and the normal area; and
a second moisture-proof pattern disposed in the link area between the pad area and the normal area.

2. The display device of claim 1, wherein the first moisture-proof pattern includes:
a moisture insulating layer supporting a side in a recessed area of a first interlayer insulating film; and
a first shielding layer including an emission layer disconnection structure on an upper portion of the recessed area.

3. The display device of claim 2, wherein the moisture insulating layer is formed of the same material as a planarization layer of the normal area.

4. The display device of claim 2, wherein the first moisture-proof pattern further includes a support structure disposed laterally adjacent to the moisture insulating layer and configured to provide support the moisture insulating layer.

5. The display device of claim 4, wherein the support structure is formed of the same material as a gate electrode of a transistor in the normal area.

6. The display device of claim 2, wherein the first shielding layer is formed of the same material as a second source-drain electrode pattern of a transistor in the normal area.

7. The display device of claim 2, wherein the first shielding layer includes:
a 1-1 metal layer;
a 1-2 metal layer disposed on the 1-1 metal layer; and
a 1-3 metal layer disposed on the 1-2 metal layer,
wherein the first shielding layer is formed in a trapezoidal shape.

8. The display device of claim 2, wherein the first shielding layer includes:
a 1-1 metal layer; and
a 1-2 metal layer disposed on the 1-1 metal layer, and having a stepped structure from the 1-1 metal layer,
wherein the first shielding layer is formed in a trapezoidal shape.

9. The display device of claim 2, wherein the second moisture-proof pattern includes a second shielding layer having a plurality of island structures spaced apart from each other in an area where a second interlayer insulating film protrudes upward.

10. The display device of claim 9, wherein the second shielding layer is provided as a plurality of second shielding layers, and a dam is included between the plurality of second shielding layers.

11. The display device of claim 9, wherein the second shielding layer includes:
a 2-1 metal layer;
a 2-2 metal layer disposed on the 2-1 metal layer; and
a 2-3 metal layer disposed on the 2-2 metal layer,
wherein the second shielding layer is formed in a trapezoidal shape.

12. The display device of claim 11, wherein the 2-1 metal layer is formed so as to protrude from a side of the 2-2 metal layer.

13. The display device of claim 9, wherein the second shielding layer includes:
a 2-1 metal layer; and
a 2-2 metal layer disposed on the 2-1 metal layer, and having a stepped structure from the 2-1 metal layer,
wherein the second shielding layer is formed in a trapezoidal shape.

14. The display device of claim 13, wherein the 2-1 metal layer is formed so as to protrude from a side of the 2-2 metal layer.

15. The display device of claim 9, wherein a height of the first interlayer insulating film, measured between a rear surface of the first interlayer insulating film and an upper surface of the first interlayer insulating film, is greater than a height of the second interlayer insulating film measured between a rear surface of the second interlayer insulating film and an upper surface of the second interlayer insulating film.

16. The display device of claim 2, wherein the second moisture-proof pattern includes a second shielding layer having a plurality of island structures spaced apart from each other within a groove formed on a second interlayer insulating film.

17. The display device of claim 16, wherein the second shielding layer includes:
a 2-1 metal layer;
a 2-2 metal layer disposed on the 2-1 metal layer; and
a 2-3 metal layer disposed on the 2-2 metal layer,
wherein the second shielding layer is formed in a trapezoidal shape.

18. The display device of claim 16, wherein the second shielding layer includes:
a 2-1 metal layer; and
a 2-2 metal layer located on the 2-1 metal layer, and having a stepped structure from the 2-1 metal layer,
wherein the second shielding layer is formed in a trapezoidal shape.

19. The display device of claim 16, wherein a height of the first interlayer insulating film, measured between a rear surface of the first interlayer insulating film and an upper surface of the first interlayer insulating film, is the same as a height of the second interlayer insulating film measured between a rear surface of the second interlayer insulating film and an upper surface of the second interlayer insulating film.

20. A display panel comprising:
a normal area where a plurality of subpixels are disposed;
an optical area where an optical electronic device is located; and
a link area where a driving signal line extends from a pad area to which a driving circuit is connected,
a first moisture-proof pattern disposed in the optical area between the optical electronic device and the normal area,
a second moisture-proof pattern disposed in the link area between the pad area and the normal area.
